(19) United States
(12) Patent Application Publication
(10) Pub. No.: US 2018/0376616 A1
(43) Pub. Date: Dec. 27, 2018

(54) LOOP HEAT PIPE AND ELECTRONIC DEVICE WITH LOOP HEAT PIPE

(71) Applicant: AURAS Technology Co., Ltd., New Taipei City (TW)

(72) Inventors: An-Chih WU, New Taipei City (TW); Chih-Wei CHEN, New Taipei City (TW)

(21) Appl. No.: 15/667,001

(22) Filed: Aug. 2, 2017

(30) Foreign Application Priority Data
Jun. 23, 2017 (TW) 106121093

(51) Int. Cl. H05K 7/20; H01L 23/427

(52) U.S. Cl. CPC H05K 7/20336; H01L 23/427; H05K 7/20327; H05K 7/20309

(57) ABSTRACT

A loop heat pipe and an electronic device with the loop heat pipe are provided. The loop heat pipe is used for removing heat from an electronic component of the electronic device. A closed loop is defined by a pipe body and an evaporator of the loop heat pipe collaboratively. A working medium flows through the closed loop. The evaporator includes a liquid/gas phase change space, a capillary structure unit and a liquid storage space. The capillary structure unit is arranged between the liquid/gas phase change space and the liquid storage space to separate the liquid/gas phase change space from the liquid storage space. A first opening end of the pipe body is connected with a space outlet. A second opening end of the pipe body is inserted into the liquid storage space through a space inlet.

### FIELD OF THE INVENTION

The present invention relates to a heat dissipation device, and more particularly to a loop heat pipe and an electronic device with the loop heat pipe.

### BACKGROUND OF THE INVENTION

With increasing development of computers and various electronic devices, people in the modern societies are used to using the computers and the electronic devices for a long time. During the operations of the computers and the electronic devices, a great deal of heat is generated. If the heat cannot be effectively dissipated away, some drawbacks occur.

For solving the above drawbacks, a loop heat pipe has been disclosed. FIG. 1 is a schematic cross-sectional view of a conventional loop heat pipe. As shown in FIG. 1, the loop heat pipe 1 comprises an evaporator 11 and a pipe body 12. A first end of the pipe body 12 is connected with an inlet 111 of the evaporator 11. A second end of the pipe body 12 is connected with an outlet 112 of the evaporator 11. Consequently, the evaporator 11 and the pipe body 12 are in communication with each other to be defined as a communication loop. A working medium 13 is a flowing material within the communication loop.

A heat source 2 is disposed on the evaporator 11. The heat generated by the heat source 2 is transferred to the evaporator 11 via conduction. After the liquid working medium 13 is introduced into the evaporator 11 through the inlet 111, the liquid working medium 13 is heated and vaporized as the gaseous working medium 13. Then, the gaseous working medium 13 is outputted from the outlet 112 of the evaporator 11 and introduced into the pipe body 12. Consequently, the gaseous working medium 13 is gradually cooled down. The cooled gaseous working medium 13 is liquefied into the liquid working medium 13. The liquid working medium 13 is introduced into the evaporator 11 through the inlet 111 again. Through the working loop of the two phase changes, the heat generated by the heat source 2 can be quickly dissipated away.

However, the conventional loop heat pipe 1 still has some problems. For example, the pipe body 12 is connected with the inlet 111 of the evaporator 11 only, but the pipe body 12 is not inserted into the evaporator 11. Moreover, the space inside the evaporator 11 is not clearly defined. Consequently, the working medium 13 vaporized in the vapor store 11 (i.e., the gaseous working medium 13) possibly flows back to the pipe body 12 through the inlet 111 of the evaporator 11. The counter-flow is not normal to the working loop. Under this circumstance, the heat dissipating efficiency is deteriorated and the working loop is interrupted.

Moreover, the inlet 111 and the outlet 112 of the evaporator 11 of the loop heat pipe 1 are located at two lateral sides of the evaporator 11. That is, the working medium 13 is exited from one side of the evaporator 11 and then introduced into the other side of the evaporator 11. Nowadays, the electronic device is developed toward light weightiness, slimness and small size. In case that the loop heat pipe 1 with a single configuration is installed in the electronic device to remove heat from the heat source 2, the flexibility of the space allocation is usually insufficient.

Therefore, the loop heat pipe needs to be further improved.

### SUMMARY OF THE INVENTION

For solving the drawbacks of the conventional technologies, the present invention provides a loop heat pipe comprising an evaporator with clearly-defined space allocation so as to avoid counter-flow of the working medium.

For solving the drawbacks of the conventional technologies, the present invention provides an electronic device with a loop heat pipe.

In accordance with an aspect of the present invention, there is provided a loop heat pipe installed in an electronic device for removing heat from an electronic component of the electronic device. The loop heat pipe includes an evaporator, a pipe body and a working medium. The evaporator may be contacted with the electronic component. The evaporator includes a liquid/gas phase change space, a capillary structure unit and a liquid storage space. The capillary structure unit is arranged between the liquid/gas phase change space and the liquid storage space to separate the liquid/gas phase change space from the liquid storage space. The liquid/gas phase change space has a space outlet. The liquid storage space has a space inlet. A closed loop is defined by the pipe body and the evaporator collaboratively. The pipe body includes a first opening end and a second opening end. The first opening end is connected with the space outlet. The second opening end is inserted into the liquid storage space through the space inlet. The working medium is filled in the evaporator and the pipe body.

In an embodiment, the working medium is exited from the evaporator through a specified side of the evaporator and introduced into the evaporator through the specified side of the evaporator, or the working medium is exited from the evaporator through a first side of the evaporator and introduced into the evaporator through a second side of the evaporator.

In an embodiment, the second opening end is inserted into the liquid storage space through the capillary structure unit and the space inlet.

In an embodiment, an insulation cover is sheathed around the second opening end so as to isolate heat energy of the evaporator.

In an embodiment, a length of the insulation cover is substantially equal to a length of the second opening end that is inserted into the evaporator.

In an embodiment, the evaporator includes a first chamber and a second chamber. The liquid/gas phase change space and the capillary structure unit are included in the first chamber. The liquid storage space is included in the second chamber. The first chamber and the second chamber are in communication with each other.

In an embodiment, the loop heat pipe further includes a heat dissipation unit. The heat dissipation unit is arranged between the first opening end and the second opening end of the pipe body.

In an embodiment, the heat dissipation unit is a cooler chip.

In an embodiment, the loop heat pipe further includes a pump. The pump is arranged between the heat dissipation unit and the second opening end of the pipe body.

In accordance with an aspect of the present invention, there is provided an electronic device. The electronic device includes an electronic component and a loop heat pipe. The loop heat pipe is used for removing heat from the electronic component. The loop heat pipe includes an evaporator, a pipe body and a working medium. The evaporator may be contacted with the electronic component. The evaporator includes a liquid/gas phase change space, a capillary structure unit and a liquid storage space. The capillary structure unit is arranged between the liquid/gas phase change space and the liquid storage space to separate the liquid/gas phase change space from the liquid storage space. The liquid/gas phase change space has a space outlet. The liquid storage space has a space inlet. A closed loop is defined by the pipe body and the evaporator collaboratively. The pipe body includes a first opening end and a second opening end. The first opening end is connected with the space outlet. The second opening end is inserted into the liquid storage space through the space inlet. The working medium is filled in the evaporator and the pipe body.

In an embodiment, the working medium is exited from the evaporator through a specified side of the evaporator and introduced into the evaporator through the specified side of the evaporator, or the working medium is exited from the evaporator through a first side of the evaporator and introduced into the evaporator through a second side of the evaporator.

In an embodiment, the second opening end is inserted into the liquid storage space through the capillary structure unit and the space inlet.

In an embodiment, an insulation cover is sheathed around the second opening end so as to isolate heat energy of the evaporator.

In an embodiment, a length of the insulation cover is substantially equal to a length of the second opening end that is inserted into the evaporator.

In an embodiment, the evaporator includes a first chamber and a second chamber. The liquid/gas phase change space and the capillary structure unit are included in the first chamber. The liquid storage space is included in the second chamber. The first chamber and the second chamber are in communication with each other.

In an embodiment, the loop heat pipe further includes a heat dissipation unit. The heat dissipation unit is arranged between the first opening end and the second opening end of the pipe body.

In an embodiment, the heat dissipation unit is a cooler chip.

In an embodiment, the loop heat pipe further includes a pump. The pump is arranged between the heat dissipation unit and the second opening end of the pipe body.

From the above descriptions, the present invention provides the loop heat pipe. The space allocations of the liquid/gas phase change space, the capillary structure unit and the liquid storage space in the evaporator are clearly defined. Since the working medium does not flow back to the pipe body, the normal working loop of the loop heat pipe can be maintained.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view of a conventional loop heat pipe;

FIG. 2 is a schematic top view illustrating a loop heat pipe and an electronic device with the loop heat pipe according to a first embodiment of the present invention;

FIG. 3 is a schematic cross-sectional view illustrating the loop heat pipe of FIG. 2;

FIG. 4 is a schematic cross-sectional view illustrating a loop heat pipe and an electronic device with the loop heat pipe according to a second embodiment of the present invention;

FIG. 5 is a schematic cross-sectional view illustrating a loop heat pipe and an electronic device with the loop heat pipe according to a third embodiment of the present invention; and

FIG. 6 is a schematic cross-sectional view illustrating a loop heat pipe and an electronic device with the loop heat pipe according to a fourth embodiment of the present invention.

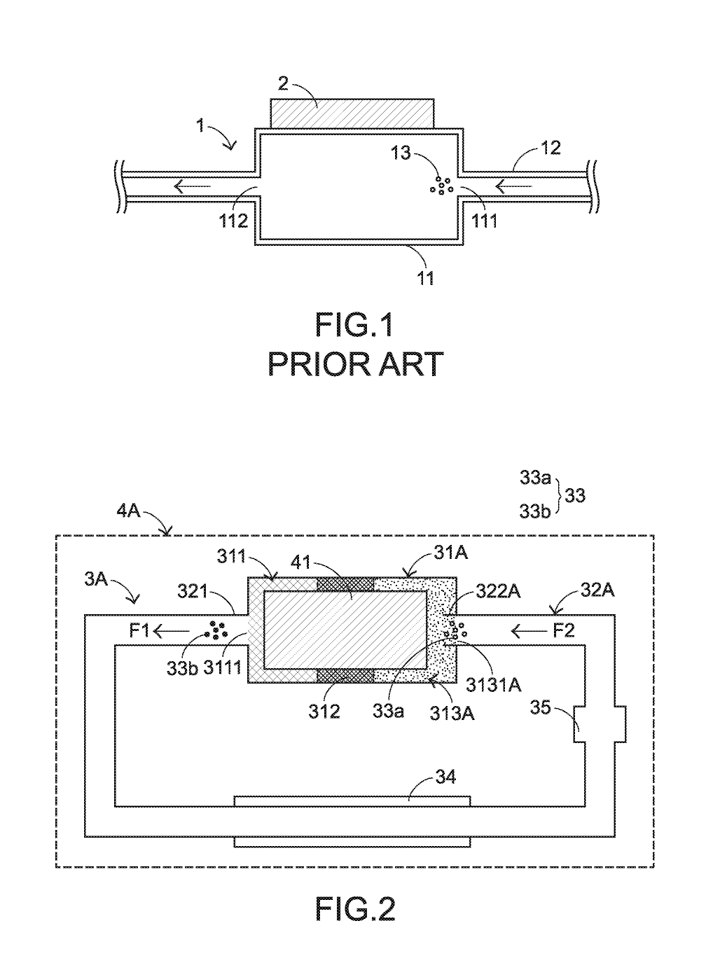

### DETAILED DESCRIPTION OF THE PREFERRED EMBODIMENT

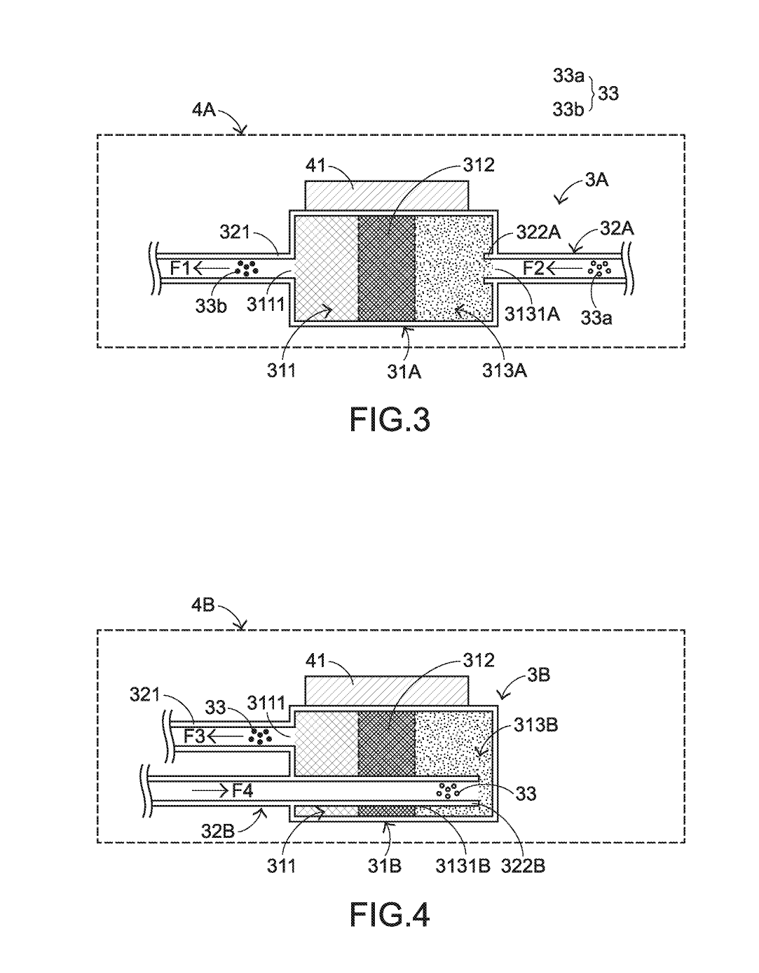

FIG. 2 is a schematic top view illustrating a loop heat pipe and an electronic device with the loop heat pipe according to a first embodiment of the present invention. FIG. 3 is a schematic cross-sectional view illustrating the loop heat pipe of FIG. 2. As shown in FIGS. 2 and 3, the loop heat pipe 3A is installed in an electronic device 4A for removing heat from the electronic component 41 of the electronic device 4A. Consequently, the electronic device 4A can be normally operated. For example, the electronic device 4A is a desktop computer, a notebook computer, a tablet computer, a mobile phone, a host, an interface card or any other device requiring better temperature control efficacy. The example of the electronic device 4A is not restricted as long as the loop heat pipe 3A can be installed therein. The electronic component 41 is a chip, a processor, a memory or any other heat-generation component during operation. Moreover, the electronic component 41 is installed on a circuit board (not shown) or a substrate (not shown) within the electronic device 4A.

In an embodiment, the loop heat pipe 3A comprises an evaporator 31A, a pipe body 32A and a working medium 33. The evaporator 31A comprises a liquid/gas phase change space 311, a capillary structure unit 312 and a liquid storage space 313A. In an embodiment, the evaporator 31A is a single-chamber evaporator, and the liquid/gas phase change space 311, the capillary structure unit 312 and the liquid storage space 313A are different segments of the single chamber. In another embodiment, the evaporator 31A is a multi-chamber evaporator, and the liquid/gas phase change space 311, the capillary structure unit 312 and the liquid storage space 313A are different chambers. Regardless of whether the evaporator 31A is the single-chamber evaporator or the multi-chamber evaporator, the capillary structure unit 312 is arranged between the liquid/gas phase change space 311 and the liquid storage space 313A. That is, the liquid/gas phase change space 311 and the liquid storage space 313A are separated from each other by the capillary structure unit 312. Moreover, the capillary structure unit 312 is a space containing a capillary structure. An example of the capillary structure includes but is not limited to a powder-sintered capillary structure, a metal-mesh capillary structure or a fiber material. The examples of the capillary structure are well known to those skilled in the art, and are not redundantly described herein.

A closed loop is defined by the pipe body 32A and the evaporator 31A collaboratively. The working medium 33 is filled in the evaporator 31A and the pipe body 32A in a gaseous form and/or a liquid form. Moreover, the working medium 33 is a medium for assisting in heat transfer. An example of the working medium 33 includes but is not limited to water or coolant. In an embodiment, the liquid/gas phase change space 311 has a space outlet 3111, and the liquid storage space 313A has a space inlet 3131A. The pipe body 32A has a first opening end 321 and a second opening end 322A. The first opening end 321 of the pipe body 32A is connected with the space outlet 3111 of the liquid/gas phase change space 311. The second opening end 322A of the pipe body 32A is inserted into the liquid storage space 313A through the space inlet 3131A of the liquid storage space 313A.

The evaporator 31A is in thermal contact with the electronic component 41. In this context, the thermal contact is the contact via thermal conduction. In accordance with the present invention, the evaporator 31A and the electronic component 41 are in direct contact with each other or in indirect contact with each other. In some embodiments, the evaporator and the electronic component are close to each other but not contacted with each other. In case that the evaporator 31A and the electronic component 41 are in direct contact with each other, the surface of the evaporator 31A is directly attached on the surface of the electronic component 41. In case that the evaporator 31A and the electronic component 41 are in indirect contact with each other, a thermal conductive medium such as thermal grease is arranged between the evaporator 31A and the electronic component 41.

The operating principles of the loop heat pipe 3A will be described as follows. The liquid working medium 33a is stored in the liquid storage space 313A of the evaporator 31A. The liquid working medium 33a in the liquid storage space 313A of the evaporator 31A is adsorbed by the capillary structure unit 312. Due to the capillary phenomenon, the liquid working medium 33a is transferred to the liquid/gas phase change space 311. After the liquid working medium 33a is transferred to the liquid/gas phase change space 311, the liquid working medium 33a absorbs the waste heat from the electronic component 41. After the liquid working medium 33a absorbs sufficient heat energy, the liquid working medium 33a is subjected to a phase change. Consequently, the liquid working medium 33a is transformed into the gaseous working medium 33b. The gaseous working medium 33b is exited from the liquid/gas phase change space 311 to the pipe body 32A through the first opening end 321 of the pipe body 32A. As shown in FIGS. 2 and 3, the gaseous working medium 33b flows along a gas flowing direction F1 to assist in heat transfer.

As the gaseous working medium 33b flows to a low-temperature site along the pipe body 32A, the heat energy is radiated to the surroundings. Consequently, the gaseous working medium 33b is subjected to the phase change again. Consequently, the gaseous working medium 33b is transformed into the liquid working medium 33a. Then, the liquid working medium 33a is introduced into the liquid storage space 313A of the evaporator 31A through the second opening end 322A of the pipe body 32A. As shown in FIGS. 2 and 3, the liquid working medium 33a flows along a liquid flowing direction F2. Through the working loop of the two phase changes, the heat generated by the electronic component 41 can be quickly dissipated away. In this embodiment, the working medium 33 is exited from the evaporator 31A through a first side of the evaporator 31A and introduced into the evaporator 31A through a second side of the evaporator 31A. That is, the working medium 33 is exited from the evaporator 31A and introduced into the evaporator 31A through different sides of the evaporator 31A.

Preferably but not exclusively, the loop heat pipe 3A further comprises a heat dissipation unit 34 and a pump 35. The heat dissipation unit 34 is arranged between the first opening end 321 and the second opening end 322A of the pipe body 32A. The pump 35 is arranged between the heat dissipation unit 34 and the second opening end 322A of the pipe body 32A. The heat dissipation unit 34 is used for removing the heat from the gaseous working medium 33b that flows within the pipe body 32A. Consequently, the rate of transforming the gaseous working medium 33b into the liquid working medium 33a is increased. An example of the heat dissipation unit 34 includes but is not limited to a cooler chip. The pump 35 is used for increasing the pressure of the working medium 33 in order to increase the pushing force of the working medium 33. Consequently, the overall looping efficacy of the loop heat pipe 3A is enhanced. Due to the arrangement of the heat dissipation unit 34, the working medium 33 has been transformed into the liquid form before flowing to the pump 35. Consequently, the use life of the pump 35 is prolonged.

FIG. 4 is a schematic cross-sectional view illustrating a loop heat pipe and an electronic device with the loop heat pipe according to a second embodiment of the present invention. The structures and functions of the loop heat pipe 3B and the electronic device 4B that are similar to those of the first embodiment are not redundantly described herein. In comparison with the first embodiment, the following aspects of this embodiment are distinguished. The working medium 33 is exited from the evaporator 31B through a specified side of the evaporator 31B. As shown in FIG. 4, the working medium 33 flows along a gas flowing direction F1. Especially, the working medium 33 is introduced into the evaporator 31B through the same specified side of the evaporator 31B. As shown in FIG. 4, the liquid working medium 33a flows along a liquid flowing direction F4. In this embodiment, the second opening end 322B of the pipe body 32B is inserted into the evaporator 31B through the specified side of the evaporator 31B that is connected with the first opening end 321 of the pipe body 32B. Moreover, the second opening end 322B of the pipe body 32B is inserted into the liquid storage space 313B through the liquid/gas phase change space 311 and the capillary structure unit 312 of the evaporator 31B and the space inlet 3131B of the liquid storage space 313B sequentially.

Nowadays, the electronic device 4B is developed toward light weightiness, slimness and small size. The loop heat pipe 3B of this embodiment has a special structure. When the loop heat pipe 3B is installed in the electronic device 4B, the flexibility of the space allocation is enhanced. Moreover, the space relationships between the liquid/gas phase change space 311, the capillary structure unit 312 and the liquid storage space 313B are clearly defined. In this embodiment, the second opening end 322B of the pipe body 32B is directly inserted into the liquid storage space 313B through the space inlet 3131B of the liquid storage space 313B. Consequently, the capillary phenomenon of the capillary structure unit 312 can drive the flowing action of the working medium 33. Moreover, since the working medium 33 vaporized in the evaporator 33 (i.e., the gaseous working medium 33) does not flow back to the pipe body 32B through the second opening end 322B of the pipe body 32B, the normal working loop of the loop heat pipe 3B can be maintained.

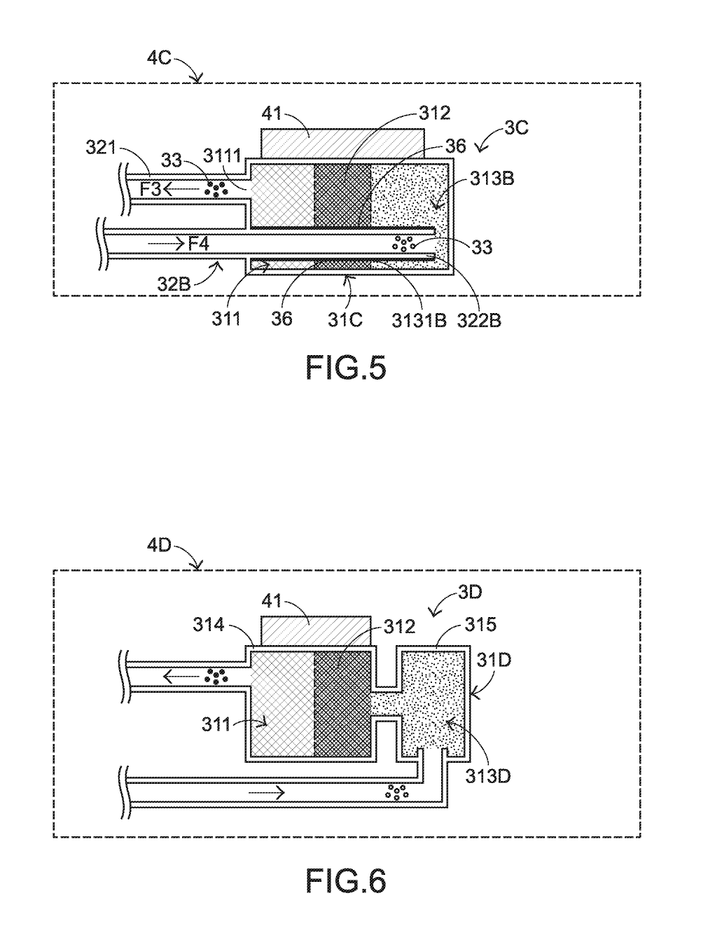

FIG. 5 is a schematic cross-sectional view illustrating a loop heat pipe and an electronic device with the loop heat pipe according to a third embodiment of the present invention. The structures and functions of the loop heat pipe 3C and the electronic device 4C that are similar to those of the first embodiment and the second embodiment are not redundantly described herein. In comparison with the first embodiment and the second embodiment, the following aspects of this embodiment are distinguished. In this embodiment, an insulation cover 36 such as a rubbery cover is sheathed around the second opening end 322B of the pipe body 32B. The insulation cover 36 is used for isolating the heat energy of the evaporator 31C. Consequently, after the liquid working medium 33 is introduced into the evaporator 31C and before the liquid working medium 33 is introduced into the liquid storage space 313B, the liquid working medium 33 is not heated and transformed into the gaseous form.

Preferably but not exclusively, the length of the insulation cover 36 is substantially equal to the length of the second opening end 322B of the pipe body 32B that is inserted into the evaporator 31C. During the process of manufacturing the loop heat pipe 3C, the insulation cover 36 is firstly sheathed around the second opening end 322B of the pipe body 32B, and then the second opening end 322B of the pipe body 32B is inserted into the evaporator 31C. According to the length of the insulation cover 36, the length of the second opening end 322B of the pipe body 32B to be inserted into the evaporator 31C is determined. Consequently, the production quality of the loop heat pipe 3C is enhanced.

FIG. 6 is a schematic cross-sectional view illustrating a loop heat pipe and an electronic device with the loop heat pipe according to a fourth embodiment of the present invention. The structures and functions of the loop heat pipe 3D and the electronic device 4D that are similar to those of the first embodiment and the second embodiment are not redundantly described herein. In comparison with the first embodiment and the second embodiment, the following aspects of this embodiment are distinguished. In this embodiment, the evaporator 31D of the loop heat pipe 3D comprises a first chamber 314 and a second chamber 315. The first chamber 314 and the second chamber 315 are in communication with each other. The liquid/gas phase change space 311 and the capillary structure unit 312 are included in the first chamber 314, and the liquid storage space 313D is included in the second chamber 315. The second chamber 315 is an external chamber that is connected with the first chamber 314. Moreover, the second opening end is still inserted into the liquid storage space 313D of the second chamber 315. However, the second opening end is not penetrated through the liquid/gas phase change space 311 and the capillary structure unit 312.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. A loop heat pipe installed in an electronic device for removing heat from an electronic component of the electronic device, the loop heat pipe comprising:
an evaporator to be contacted with the electronic component, wherein the evaporator comprises a liquid/gas phase change space, a capillary structure unit and a liquid storage space, wherein the capillary structure unit is arranged between the liquid/gas phase change space and the liquid storage space to separate the liquid/gas phase change space from the liquid storage space, the liquid/gas phase change space has a space outlet, and the liquid storage space has a space inlet;
a pipe body, wherein a closed loop is defined by the pipe body and the evaporator collaboratively, wherein the pipe body comprises a first opening end and a second opening end, the first opening end is connected with the space outlet, and the second opening end is connected with the space inlet of the liquid storage space by inserting through the liquid/gas phase change space and the capillary structure unit; and
a working medium filled in the evaporator and the pipe body.

2. The loop heat pipe according to claim 1, wherein the working medium is exited from the evaporator through a specified side of the evaporator and introduced into the evaporator through the specified side of the evaporator, or the working medium is exited from the evaporator through a first side of the evaporator and introduced into the evaporator through a second side of the evaporator.

3. (canceled)

4. The loop heat pipe according to claim 31, wherein an insulation cover is sheathed around the second opening end so as to isolate heat energy of the evaporator.

5. The loop heat pipe according to claim 4, wherein a length of the insulation cover is substantially equal to a length of the second opening end that is inserted into the evaporator.

6. The loop heat pipe according to claim 1, wherein the evaporator comprises a first chamber and a second chamber, wherein the liquid/gas phase change space and the capillary structure unit are included in the first chamber, and the liquid storage space is included in the second chamber, wherein the first chamber and the second chamber are in communication with each other.

7. The loop heat pipe according to claim 1, further comprising a heat dissipation unit, wherein the heat dissipation unit is arranged between the first opening end and the second opening end of the pipe body.

8. The loop heat pipe according to claim 7, wherein the heat dissipation unit is a cooler chip.

9. The loop heat pipe according to claim 7, further comprising a pump, wherein the pump is arranged between the heat dissipation unit and the second opening end of the pipe body.

10. An electronic device, comprising:
an electronic component; and
a loop heat pipe for removing heat from the electronic component, wherein the loop heat pipe comprises:
an evaporator to be contacted with the electronic component, wherein the evaporator comprises a liquid/gas phase change space, a capillary structure unit and a liquid storage space, wherein the capillary structure unit is arranged between the liquid/gas phase change space and the liquid storage space to separate the liquid/gas phase change space from the liquid storage space, the liquid/gas phase change space has a space outlet, and the liquid storage space has a space inlet;
a pipe body, wherein a closed loop is defined by the pipe body and the evaporator collaboratively, wherein the pipe body comprises a first opening end and a second opening end, the first opening end is connected with the space outlet, and the second opening end is connected with the space inlet of the liquid storage space by inserting through the liquid/gas phase change space and the capillary structure unit; and
a working medium filled in the evaporator and the pipe body.

11. The electronic device according to claim 10, wherein the working medium is exited from the evaporator through a specified side of the evaporator and introduced into the evaporator through the specified side of the evaporator, or the working medium is exited from the evaporator through a first side of the evaporator and introduced into the evaporator through a second side of the evaporator.

12. (canceled)

13. The electronic device according to claim 10, wherein an insulation cover is sheathed around the second opening end so as to isolate heat energy of the evaporator.

14. The electronic device according to claim 13, wherein a length of the insulation cover is substantially equal to a length of the second opening end that is inserted into the evaporator.

15. The electronic device according to claim 10, wherein the evaporator comprises a first chamber and a second chamber, wherein the liquid/gas phase change space and the capillary structure unit are included in the first chamber, and the liquid storage space is included in the second chamber, wherein the first chamber and the second chamber are in communication with each other.

16. The electronic device according to claim 10, wherein the loop heat pipe further comprises a heat dissipation unit, and the heat dissipation unit is arranged between the first opening end and the second opening end of the pipe body.

17. The electronic device according to claim 16, wherein the heat dissipation unit is a cooler chip.

18. The electronic device according to claim 16, wherein the loop heat pipe further comprises a pump, and the pump is arranged between the heat dissipation unit and the second opening end of the pipe body.

19. A loop heat pipe installed in an electronic device for removing heat from an electronic component of the electronic device, the loop heat pipe comprising:
an evaporator to be contacted with the electronic component, wherein the evaporator comprises:
a first chamber;
a second chamber separated from the first chamber; and
a connection channel connected between the first chamber and the second chamber, and the connection channel having a width less than a width of the second chamber,
wherein a liquid/gas phase change space and a capillary structure unit are included in the first chamber, and a liquid storage space is included in the second chamber and the connection channel, and the capillary structure unit is arranged between the liquid/gas phase change space and the liquid storage space to separate the liquid/gas phase change space from the liquid storage space, and the liquid/gas phase change space has a space outlet, and the liquid storage space has a space inlet;
a pipe body, wherein a closed loop is defined by the pipe body and the evaporator collaboratively, wherein the pipe body comprises a first opening end and a second opening end, the first opening end is connected with the space outlet, and the second opening end is inserted into the liquid storage space through the space inlet; and
a working medium filled in the evaporator and the pipe body.

20. The loop heat pipe according to claim 19, wherein the width of connection channel is less than a width of the first chamber.
